(19) United States
(12) Patent Application Publication
(10) Pub. No.: US 2009/0033434 A1
(43) Pub. Date: Feb. 5, 2009

(54) OSCILLATION CIRCUIT

(75) Inventors: Takeshi Ikeda, Tokyo (JP); Hiroshi Miyagi, Kanagawa (JP)

Correspondence Address: CONNOLLY BOVE LODGE & HUTZ LLP, 1875 EYE STREET, N.W., SUITE 1100, WASHINGTON, DC, 20006, US

(73) Assignees: NIIGATA SEIMITSU CO., LTD., NIIGATA (JP); RICOH CO., LTD., TOKYO (JP)

(21) Appl. No.: 12/280,124

(22) PCT Filed: Sep. 28, 2006
(86) PCT No.: PCT/JP2006/319902

§ 371 Date: Aug. 20, 2008

(30) Foreign Application Priority Data
Feb. 20, 2006 (JP) 2006-042413

(51) Int. Cl. H03B 5/08

(52) U.S. Cl. 331/36 C

(57) ABSTRACT

A first switch (SW1) is connected in series between a first capacitor (1) and a grounding wire, and when an RTC oscillation apparatus is connected and an IC chip (10) is configured as an external input buffer circuit, the first switch (SW1) is turned off. Thus, the first capacitor (1) and a second capacitor (2) are prevented from being connected in parallel to a resonance capacitor of the RTC oscillation apparatus, and the first and the second capacitors (1, 2) are prevented from configuring a part of the resonance circuit of the oscillation apparatus. When an exclusive crystal oscillator is connected and the IC chip (10) is configured as a part of the oscillation apparatus, the first switch (SW1) is turned on and the first and the second capacitors (1, 2) configure a part of the resonance circuit.

### TECHNICAL FIELD

The present invention relates to an oscillation circuit and particularly suitable for an oscillation circuit integrated into a semiconductor chip.

### BACKGROUND ART

In general, clock circuits showing a real time (Real Time Clock: RTC) are provided in information processors such as mobile phones or PDAs (Personal Digital Assistants). RTCs are used not only for time display as typical clocks but also, for example, for recording time of receipt at call register in mobile phones and for calendar functions in PDAs.

Since a reference frequency of an RTC is required to be accurate, a highly accurate oscillator, for example a crystal oscillator, is used as an oscillation apparatus for reference frequency oscillation. FIG. 1 is a diagram showing a configuration of a conventional RTC oscillation apparatus. As shown in FIG. 1, the conventional RTC oscillation apparatus comprises an oscillation circuit 100, a crystal oscillator 101 and two capacitors 102 and 103. An oscillation frequency thereof depends on capacitances of the capacitors 102 and 103.

Additionally, information processors become more multifunctional and various services are available recently. For example, there are apparatuses including an FM broadcasting receiving function, apparatuses including an MP3 player, apparatuses including a transmitter function FM-modulating an audio signal for radio transmission, and the like. In multifunctional information processors like these, it is necessary to produce different reference frequencies for respective circuits in order to obtain different process frequencies necessary at circuits of respective functions.

Therefore, set makers for information processors prepare oscillation apparatus for producing a reference frequency necessary at a circuit having a function to be packaged other than RTC oscillation apparatus and information processors have these integrated. In this case, commercial oscillation circuits as IC chips are often used as oscillators suitable for circuits having respective functions. FIG. 2 is a diagram showing an exemplary configuration of an oscillation apparatus formed by using an IC chip (for example, see Patent Document 1).

Patent Document 1: Japanese Patent Laid-Open No.

As shown in FIG. 2, a conventional oscillation apparatus comprises: a crystal oscillator 111; a capacitor 112 connected between one end of the crystal oscillator 111 and a grounding wire; a capacitor 113 connected between the other end of the crystal oscillator 111 and a grounding wire; and an inverting amplifier 114 and a feedback resistance 115 connected in parallel between both ends of the crystal oscillator 111. Then, an oscillation circuit except the crystal oscillator 111 is integrated into an IC chip 116.

In the oscillation apparatus shown in FIG. 2, a oscillation frequency substantially depends on a resonance frequency of a resonance circuit including the crystal oscillator 111, the capacitors 112 and 113, and strictly, is determined by series equivalent capacitance (i.e. load capacitance) including the inverting amplifier 114 viewed from the crystal oscillator 111. In order to obtain a process frequency necessary at a functional circuit to be packaged in an information processor, a set maker for the information processor generally uses the commercial IC chip 116 having the capacitors 112 and 113 with a required capacitance. Then, the crystal oscillator 111 oscillating at a required frequency as an external component of the IC chip 116 is connected thereto, so that an oscillation apparatus producing a required reference frequency is formed.

By the way, the IC chip 116 shown in FIG. 2 may be used as an external input buffer circuit capturing a reference signal produced at an external oscillation apparatus. For example, the RTC oscillation apparatus shown in FIG. 1 is connected to the IC chip 116 so that it is possible to use the IC chip 116 as an external input buffer circuit capturing a reference signal produced at the RTC oscillation apparatus.

FIG. 3 is a diagram showing an exemplary conventional configuration in the case of using the IC chip 116 as the external input buffer circuit. In FIG. 3, components having the same functions as the components shown in FIGS. 1 and 2 have the same reference numerals. In FIG. 3, a coupling capacitor 117 for cutting a direct current (DC) component is connected between the RTC oscillation apparatus and the IC chip 116.

### DISCLOSURE OF THE INVENTION

As described above, it is possible to use the IC chip 116 shown in FIG. 2 as an oscillation apparatus by connecting the crystal oscillator 111 thereto or as an external input buffer circuit by connecting an external oscillation apparatus thereto.

However, if the IC chip 116 is used as the external input buffer circuit as shown in FIG. 3, since one pair of resonance capacitors 102, 103 and the other pair of resonance capacitors 112, 113 are double connected to the one crystal oscillator 101, there is a problem that a capacitance value added to the crystal oscillator 101 varies and an oscillation frequency goes wrong. An oscillation operation may stop in the worst case. There is also a problem that the coupling capacitor 117 must be provided as an external component of the IC chip 116.

The present invention has been made for solving these problems and has a first object that an oscillation operation of an oscillator does not go wrong even if using an IC chip as an external input buffer circuit in the case where an information processor is formed by using the IC chip usable as any of a part of an oscillation apparatus producing a reference signal or an external input buffer circuit for a reference signal supplied from an external oscillation apparatus.

The present invention also has a second object that an additional coupling capacitor does not have to be provided as an external component even if using the IC chip as an external input buffer circuit in the case where an information processor is formed by using the IC chip usable as any of a part of an oscillation apparatus producing a reference signal or an external input buffer circuit for a reference signal supplied from an external oscillation apparatus.

In order to solve the problems, in the present invention, a switch is connected to a capacitor connected between an oscillator and a grounding wire and the switch is controlled for switching so that it is possible to switch presence or absence of a connection of the capacitor to the grounding wire.

In another aspect of the present invention, a switch is connected to a capacitor and the switch is controlled for switching so that it is possible to switch either connecting the capacitor to a grounding wire or connecting the capacitor in series to a buffer circuit including an amplifier circuit.

According to the present invention with the above configuration, when the capacitor is connected between the oscillator and the grounding wire by switching the switch, the capacitor can be used as a resonance capacitor. Because of this, in the case of an oscillation apparatus formed by connecting the oscillator to a semiconductor chip, the switch is controlled for switching so as to connect the capacitor between the oscillator and the grounding wire so that the capacitor is typically used as a resonance capacitor. As a result, a desired oscillation frequency can be produced.

Also, according to the present invention, it is possible to cut a connection of the capacitor to the grounding wire and connect the capacitor in series to the buffer circuit by switching the switch. Because of this, in the case of a semiconductor chip having an external oscillation apparatus connected as the external input buffer circuit, the switch is controlled for switching so as to connect the capacitor in series to the buffer circuit so that the capacitor in the semiconductor chip is not connected in parallel to the resonance capacitor used in the external oscillation apparatus. As a result, it can be prevented that an oscillation frequency of an oscillator goes wrong. Additionally, in this case, the capacitor in the semiconductor chip can function as a coupling capacitor for cutting a DC component, and therefore, an additional coupling capacitor does not have to be provided as an external component of the semiconductor chip.

### BRIEF DESCRIPTION OF THE DRAWINGS

FIG. 1 is a diagram showing a configuration of a conventional RTC oscillation apparatus;

FIG. 2 is a diagram showing a configuration of an oscillation circuit integrated into a conventional IC chip;

FIG. 3 is a diagram showing an exemplary connection of the conventional RTC oscillation apparatus and IC chip;

FIG. 4 is a diagram showing an exemplary configuration of an oscillation circuit according to a first embodiment;

FIG. 5 is a diagram showing a circuit formed in the case where a first control signal Ctl1 is “Hi” and a second control signal Ctl2 is “Lo” in the first embodiment;

FIG. 6 is a diagram showing a circuit formed in the case where the first control signal Ctl1 is “Lo” and the second control signal Ctl2 is “Hi” in the first embodiment;

FIG. 7 is a diagram showing an exemplary configuration of an oscillation circuit according to a second embodiment;

FIG. 8 is a diagram showing an exemplary configuration of an oscillation circuit according to a third embodiment;

FIG. 9 is a diagram showing a circuit formed in the case where a first control signal Ctl1 is “Hi” and a second control signal Ctl2 is “Lo” in the third embodiment;

FIG. 10 is a diagram showing a circuit formed in the case where the first control signal Ctl1 is “Lo” and the second control signal Ctl2 is “Hi” in the third embodiment;

FIG. 11 is a diagram showing an exemplary configuration of an oscillation circuit according to a fourth embodiment;

FIG. 12 is a diagram showing a circuit formed in the case of selecting a terminal a of a switch in the fourth embodiment;

FIG. 13 is a diagram showing a circuit formed in the case of selecting a terminal b of the switch in the fourth embodiment; and

FIG. 14 is a diagram showing an exemplary configuration of an oscillation circuit according to a fifth embodiment.

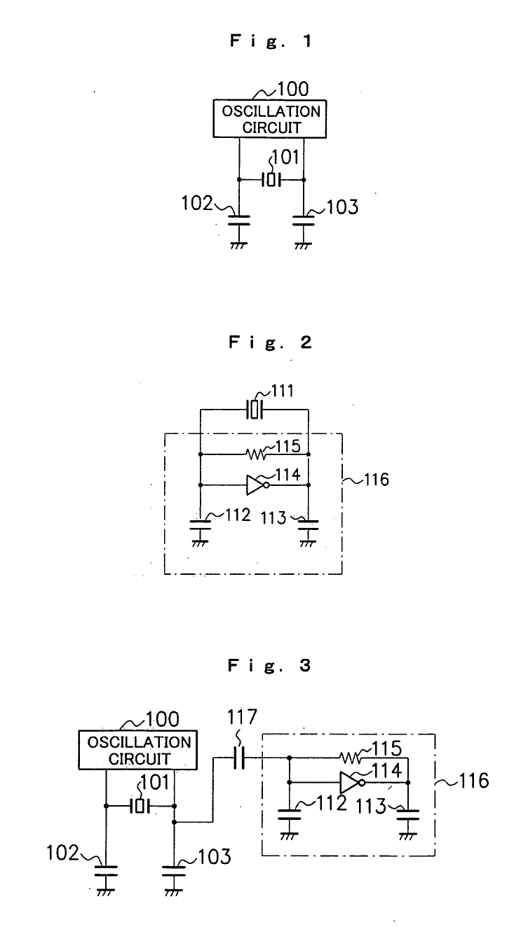

### BEST MODE FOR CARRYING OUT THE INVENTION

### First Embodiment

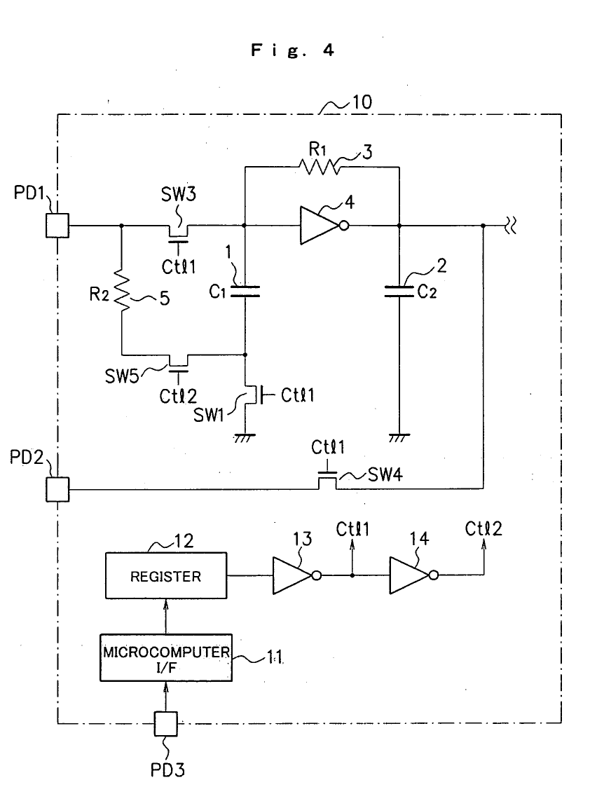

Hereinafter, an embodiment of the present invention is described with reference to the drawings. FIG. 4 is a diagram showing an exemplary configuration of an oscillation circuit according to a first embodiment. In FIG. 4, reference numeral 10 denotes an IC chip having respective components described below integrated, for example, in a CMOS (Complementary Metal Oxide Semiconductor) process.

Reference characters PD1, PD2 and PD3 denote pads of the IC chip 10. Reference character PD1 denotes a first pad having one end of a crystal oscillator (not shown) connected, reference character PD2 denotes a second pad having the other end of the crystal oscillator connected, and reference character PD3 denotes a fourth pad connected to a not-shown microcomputer. The crystal oscillator is connected to the first pad PD1 and the second pad PD2 directly, or through a divider, a multiplier or the like (not shown).

Reference numeral 1 denotes a first capacitor connected between the first pad PD1 and a grounding wire and having a capacitance C₁, reference numeral 2 denotes a second capacitor connected between the second pad PD2 and a grounding wire and having a capacitance C₂. Additionally, reference numeral 3 denotes a feedback resistance of a resistance value R₁, reference numeral 4 denotes an inverting amplifier, and these are connected in parallel between the first and second pads PD1 and PD2.

Reference character SW1 denotes a first switch connected in series to the first capacitor 1 between the first pad PD1 and the grounding wire. In the embodiment, the first switch SW1 is connected between one end of the first capacitor 1 and the grounding wire. Reference character SW3 denotes a third switch connected between the first pad PD1 and a common input terminal of the feedback resistance 3 and the inverting amplifier 4.

Reference character SW4 denotes a fourth switch connected between the second pad PD2 and a common output terminal of the feedback resistance 3 and the inverting amplifier 4. Reference character SW5 denotes a fifth switch connected in parallel to the third switch SW3 between one end of the first capacitor 1 (a node between the first capacitor 1 and the first switch SW1) and the first pad PD1. A resistance 5 with a resistance value R₂ is connected between the fifth switch SW5 and the first pad PD1.

Reference numeral 11 denotes a microcomputer I/F (interface) inputting a control signal from a not-shown microcomputer. Reference numeral 12 denotes a register storing the control signal input from the microcomputer I/F 11. Reference numerals 13 and 14 denote inverters inverting logic of the control signal stored in the register 12 and outputting the result. The first inverter 13 inverts the logic of the control signal output from the register 12 to output a first control signal Ctl1. The second inverter 14 inverts logic of the first control signal Ctl1 output from the first inverter 13 to output a second control signal Ctl2 having an opposite phase to the first control signal Ctl1.

The first and second control signals Ctl1 and Ctl2 are signals for controlling the respective switches SW1, SW3, SW4 and SW5. The first control signal Ctl1 controls on/off of the first, third and fourth switches SW1, SW3 and SW4, and the second control signal Ctl2 controls on/off of the fifth switch SW5. Each of the switches SW1, SW3, SW4 and SW5 is turned on when a control signal input to its control terminal is at “Hi” level, and turned off when the control signal is at “Lo” level.

Here, in order to obtain a reference frequency necessary at a circuit such as an FM broadcasting receiving function, an MP3 playback function or an FM transmitter function, when an exclusive crystal oscillator for the circuit is connected to the first and second pads PD1 and PD2, a control signal for setting the first control signal Ctl1 “Hi” and the second control signal Ctl2 “Lo”, that is, a “Lo” level control signal is sent from a not-shown microcomputer to the IC chip 10. Then, the control signal is input from the microcomputer I/F 11 to be held in the register 12.

On the other hand, when the IC chip 10 is used as an external input buffer circuit inputting a reference frequency signal produced by using an external crystal oscillator such as an RTC oscillation apparatus, a control signal for setting the first control signal Ctl1 “Lo” and the second control signal Ctl2 “Hi”, that is, a “Hi” level control signal is sent from the not-shown microcomputer to the IC chip 10. Then, the control signal is input from the microcomputer I/F 11 to be held in the register 12.

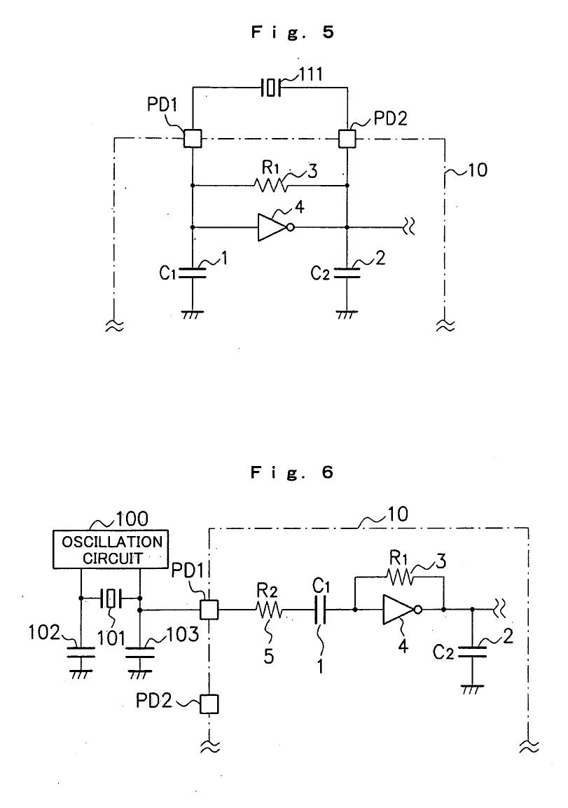

FIG. 5 is a diagram showing a circuit formed in the case where the first control signal Ctl1 is “Hi” and the second control signal Ctl2 is “Lo”. As shown in FIG. 5, the capacitors 1 and 2 are respectively connected to ends of an exclusive crystal oscillator 111 provided outside the IC chip 10 and a resonance circuit is formed by grounding the capacitors 1 and 2 to obtain a grounding potential. Then, the feedback resistance 3 and the inverting amplifier 4 are connected in parallel between both ends of the crystal oscillator 111 and an oscillation frequency of the resonance circuit is feedback-amplified. In this manner, a crystal oscillation apparatus is formed with the crystal oscillator 111, the first and second capacitors 1 and 2, the feedback resistance 3 and the inverting amplifier 4.

FIG. 6 is a diagram showing a circuit formed in the case where the first control signal Ctl1 is “Lo” and the second control signal Ctl2 is “Hi”. As shown in FIG. 6, an RTC oscillation apparatus including, for example, the oscillation circuit 100, the crystal oscillator 101 and the two capacitors 102 and 103 is provided outside the IC chip 10 and an oscillation output thereof is connected to the first pad PD1 of the IC chip 10.

The resistance 5 and the first capacitor 1 are connected in series to the first pad PD1, and further, the feedback resistance 3 and the inverting amplifier 4 are connected in parallel to a subsequent stage thereof. The second capacitor 2 is connected between an output terminal of the inverting amplifier 4 and a grounding wire. Thus, in the case where the first control signal Ctl1 is “Lo” and the second control signal Ctl2 is “Hi”, the first capacitor 1 functions as a coupling capacitor for cutting a DC component, the whole IC chip 10 forms a DC cut filter, and a cut-off frequency f_{c} thereof is obtained by:

f_{c}=½πC₁(R₁+R₂)

As described above, when the first control signal Ctl1 is “Hi” and the second control signal Ctl2 is “Lo”, the resonance circuit is formed by the first and second capacitors 1 and 2. At the time, an oscillation frequency depends on capacitances of the capacitors 1 and 2 because a resonance frequency is determined with the crystal oscillator 111 being an inductor component and the first and second capacitors 1 and 2 being capacitance components.

On the other hand, when the first control signal Ctl1 is “Lo” and the second control signal Ctl2 is “Hi”, the first and second capacitors 1 and 2 are not a part of the resonance circuit, which can prevent the occurrence of distortion in oscillation frequencies of the crystal oscillator 101. Also, according to the embodiment, the first capacitor 1 can be connected in series between the RTC oscillation apparatus and the inverting amplifier 4 so that the first capacitor 1 functions as the coupling capacitor for cutting a DC, which avoid the necessity for providing a capacitor for cutting a DC as an external component of the IC chip 10.

As described in detail above, according to the embodiment, in the case where a information processor such as a mobile phone or a PDA is formed by using the IC chip 10 having an oscillation circuit including resonance capacitors 1 and 2 integrated, on/off of the switches SW1, SW3, SW4 and SW5 is switched depending on either using the IC chip 10 as a part of an oscillation apparatus producing a reference signal or using the IC chip 10 as an external input buffer circuit for a reference signal supplied from an external oscillation apparatus. As a result, the IC chip 10 can be used properly as the situation demands.

### Second Embodiment

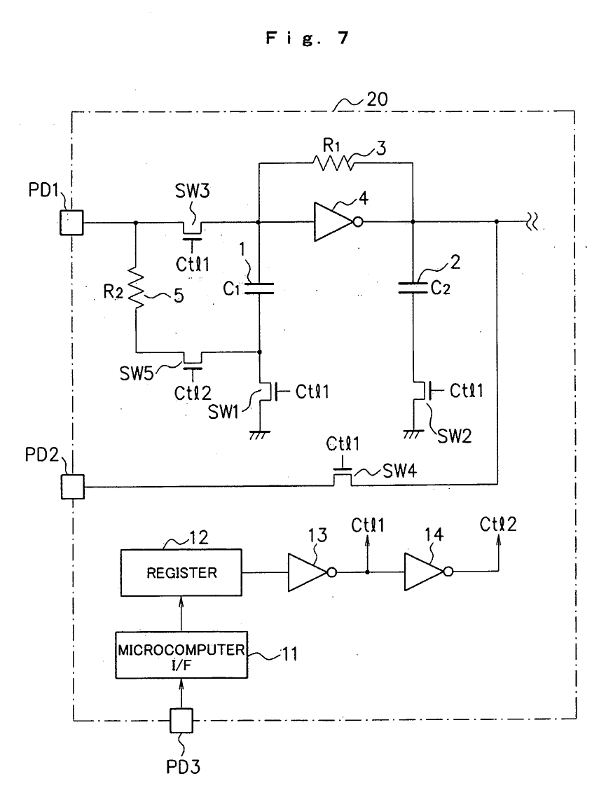

Next, a second embodiment of the present invention is described with reference to the drawings. FIG. 7 is a diagram showing an exemplary configuration of an oscillation circuit (an IC chip 20) according to the second embodiment. In FIG. 7, since some of the components with reference characters similar to the reference characters shown in FIG. 4 have similar functions, redundant description is omitted here.

In the second embodiment, a second switch SW2 is provided between the second capacitor 2 and a grounding wire. That is, the second capacitor 2 and the second switch SW2 are connected in series between the second pad PD2 and the grounding wire. On/off of the second switch SW2 is controlled by the first control signal Ctl1.

Various oscillation apparatuses, including the above RTC oscillation apparatus, producing a various frequency different from a frequency of the RTC oscillation apparatus can be used as an external crystal oscillation apparatus connected to the IC chip 20. For example, if a high frequency is produced at the external crystal oscillation apparatus of the IC chip 20 to be input to the IC chip 20, it is preferable that the second capacitor 2 connected to an output of the inverting amplifier 4 is also cut off. In the second embodiment, the “Lo” first control signal Ctl1 can turn off the second switch SW2 and cut off the connection of the second capacitor 2.

### Third Embodiment

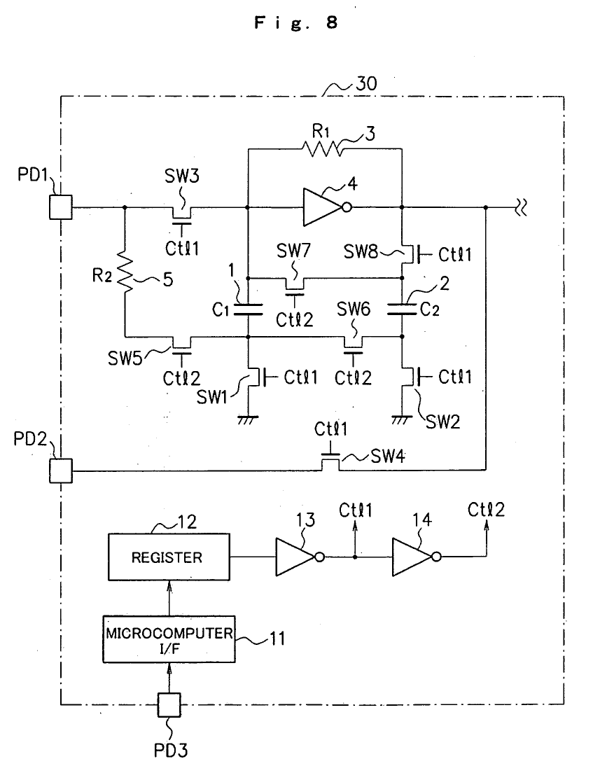

Next, a third embodiment of the present invention is described with reference to the drawings. FIG. 8 is a diagram showing an exemplary configuration of an oscillation circuit (an IC chip 30) according to the third embodiment. In FIG. 8, since some of the components with reference characters similar to the reference characters shown in FIG. 7 have similar functions, redundant description is omitted here.

In the third embodiment, sixth to eighth switches SW6 to SW8 are further provided in addition to the configuration shown in FIG. 7. The sixth switch SW6 is connected between one end of the first capacitor 1 and one end of the second capacitor 2. The seventh switch SW7 is connected between the other end of the first capacitor 1 and the other end of the second capacitor 2. The eighth switch SW8 is connected between an output terminal of the inverting amplifier 4 and the other end of the second capacitor 2. The sixth and seventh switches SW6 and SW7 are turned on or off by the second control signal Ctl2 and the eighth switch SW8 is turned on or off by the first control signal Ctl1.

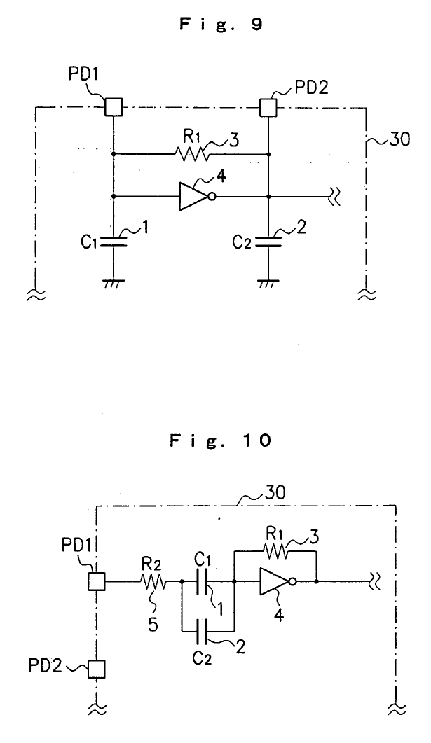

FIG. 9 is a diagram showing a circuit formed in the case where the first control signal Ctl1 is “Hi” and the second control signal Ctl2 is “Lo” in the third embodiment. A circuit configuration shown in FIG. 9 is quite similar to a circuit configuration shown in FIG. 5.

FIG. 10 is a diagram showing a circuit formed in the case where the first control signal Ctl1 is “Lo” and the second control signal Ctl2 is “Hi” in the third embodiment. In a circuit configuration shown in FIG. 10 different from a circuit configuration shown in FIG. 6, the first and second capacitors 1 and 2 are connected in parallel between the resistance 5 and the inverting amplifier 4.

In this case, a cut-off frequency f_{c}′ of a DC cut filter is obtained by

f_{c}′=½π(C₁+C₂)(R₁+R₂)

and the cut-off frequency f_{c}′ is lower than the cut-off frequency f_{c} in the first embodiment in FIG. 6. Thus, according to the third embodiment, an operation without problems is possible even if a low frequency is produced at the external crystal oscillation apparatus of the chip to be input to the IC chip 30.

### Fourth Embodiment

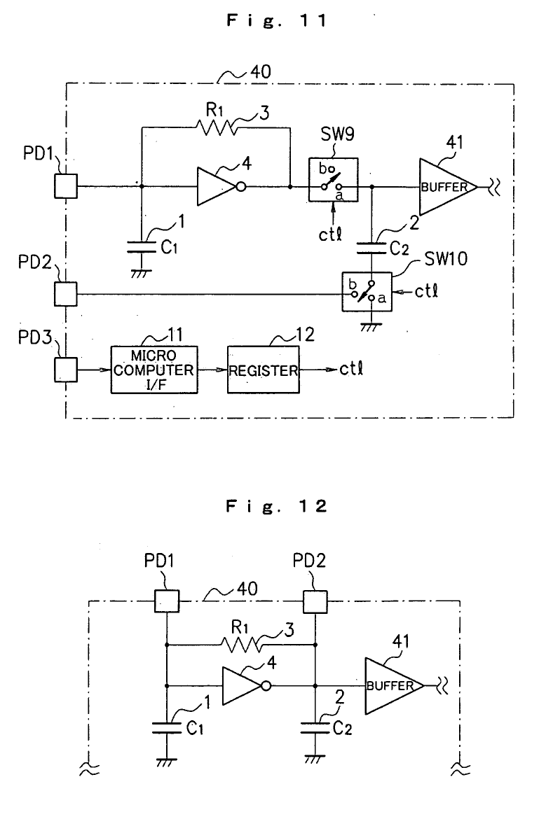

Next, a fourth embodiment of the present invention is described with reference to the drawings. FIG. 11 is a diagram showing an exemplary configuration of an oscillation circuit (an IC chip 40) according to the fourth embodiment. In FIG. 11, since some of the components with reference characters similar to the reference characters shown in FIG. 4 have similar functions, redundant description is omitted here.

In FIG. 11, the first capacitor 1 is connected between the first pad PD1 and a grounding wire. A parallel circuit of the feedback resistance 3 and the inverting amplifier 4, a ninth switch SW9, and a buffer circuit 41 are connected in series to the first pad PD1. A terminal being a branch origin of the ninth switch SW9 is connected to the parallel circuit of the feedback resistance 3 and the inverting amplifier 4. Also, a terminal a, which is one of two terminals being branch destinations, is connected to the buffer circuit 41 and the second capacitor 2, while a terminal b is opened.

Additionally, a tenth switch SW10 is connected between the second pad PD2, the second capacitor 2 and a grounding wire. A terminal being a branch origin of the tenth switch SW10 is connected to the second capacitor 2. Also, a terminal a, which is one of two terminals being branch destinations, is connected to the grounding wire, while a terminal b is connected to the second pad PD2.

The microcomputer I/F 11 inputs a control signal Ctl from a not-shown microcomputer through the third pad PD3. The register 12 temporarily stores and outputs a control signal Ctl input from the microcomputer I/F 11. The control signal Ctl is a signal for switching the ninth and tenth switches SW9 and SW10 to either the terminal a sides or the terminal b sides.

Here, in order to obtain a reference frequency necessary at a circuit such as an FM broadcasting receiving function, an MP3 playback function or an FM transmitter, when an exclusive crystal oscillator for the circuit is connected to the first and second pads PD1 and PD2, the control signal Ctl switching the ninth and tenth switches SW9 and SW10 to the terminal a sides is sent from a not-shown microcomputer to the IC chip 40. Then, the control signal Ctl is input from the microcomputer I/F 11 to be held in the register 12.

On the other hand, when the IC chip 40 is used as an external input buffer circuit inputting a reference frequency signal produced by using an external crystal oscillator such as an RTC oscillation apparatus, the control signal Ctl switching the ninth and tenth switches SW9 and SW10 to the terminal b sides is sent from the not-shown microcomputer to the IC chip 40. Then, the control signal is input from the microcomputer I/F 11 to be held in the register 12.

FIG. 12 is a diagram showing a circuit formed in the case of switching the ninth and tenth switches SW9 and SW10 to the terminal a sides. In this case, a crystal oscillator is connected to the pads PD1 and PD2 so that it is possible to form a crystal oscillation apparatus with the crystal oscillator and the IC chip 40. In FIG. 12, the buffer circuit 41 buffering a reference signal produced from the crystal oscillation apparatus is also integrated into the IC chip 40.

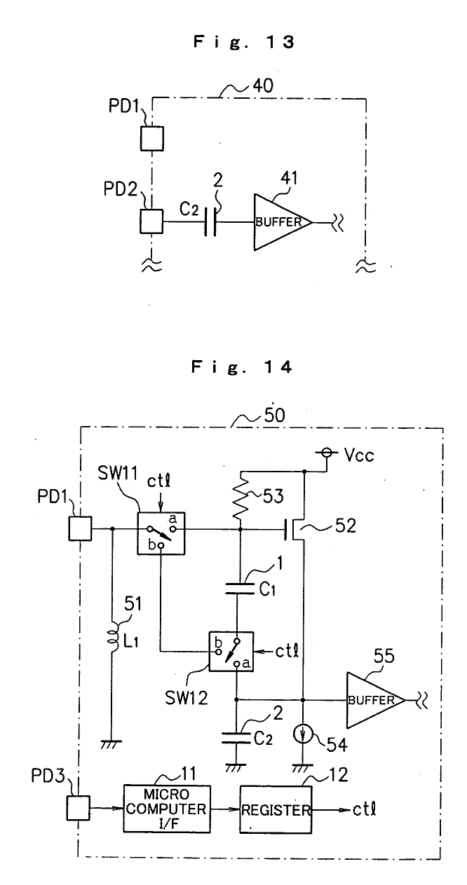

FIG. 13 is a diagram showing a circuit formed in the case of switching the ninth and tenth switches SW9 and SW10 to the terminal b sides. In this case, an RTC oscillation apparatus, for example, is provided outside the IC chip 40 and an oscillation output thereof is connected to the second pad PD2 of the IC chip 40. The second capacitor 2 and the buffer circuit 41 are connected in series to the second pad PD2. In this manner, the second capacitor 2 functions as a coupling capacitor for cutting a DC component in the case of switching the ninth and tenth switches SW9 and SW10 to the terminal b sides.

The IC chip 40 with the above configuration according to the fourth embodiment is useful for making the feedback resistance 3 by a cascade connection of a plurality of transistors to increase the resistance value R₁ of the feedback resistance 3 (for realizing the resistance value R₁ by on resistances of transistors). In the case of realizing the resistance value R₁ of the feedback resistance 3 by on resistances of transistors, if the external input buffer circuit is formed as shown in FIG. 6, a bias is shifted when a large signal is input and an output waveform has a distortion. Because a linear operating range of the transistor is narrow.

On the other hand, in the fourth embodiment, the feedback resistance 3 is in use when the IC chip 40 is a part of the oscillation apparatus, while the buffer circuit 41 is in use and the feedback resistance 3 is not in use as shown in FIG. 13 when the IC chip 40 is an external input buffer circuit. Because of this, the above disadvantage can be avoided even if the feedback resistance 3 is made by transistors to increase the resistance value R₁.

### Fifth Embodiment

Next, a fifth embodiment of the present invention is described with reference to the drawings. While a CR oscillation circuit is described as an example in the first to fourth embodiments, the present invention can be also applied to, for example, an LC back coupling oscillator circuit such as a Colpitts oscillation circuit or a clapp oscillation circuit, which is another kind of a Colpitts oscillation circuit.

FIG. 14 is a diagram showing an exemplary configuration of an oscillation circuit (an IC chip 50) according to the fifth embodiment. The fifth embodiment shown in FIG. 14 shows an exemplary configuration of a clapp oscillation circuit. In FIG. 14, the clapp oscillation circuit comprises the first and second capacitors 1 and 2 having capacitances C₁ and C₂ respectively, a coil 51 having an inductance L₁, a transistor 52, a bias resistance 53, and a constant current source 54. This configuration is well known.

In the fifth embodiment, the clapp oscillation circuit above described is connected to the first pad PD1. A buffer circuit 55 is connected to an output of the clapp oscillation circuit. Additionally, a eleventh switch SW11 is connected between the first pad PD1 and the first capacitor 1 and a twelfth switch SW12 is connected between the first capacitor 1, the second capacitor 2 and the eleventh switch SW11.

A terminal being a branch origin of the eleventh switch SW11 is connected to the first pad PD1. Also, a terminal a, which is one of two terminals being branch destinations, is connected to the first capacitor 1, while a terminal b is connected to a terminal b of the twelfth switch SW12. A terminal being a branch origin of the twelfth switch SW12 is connected to the first capacitor 1. Also, a terminal a, which is one of two terminals being branch destinations, is connected to the second capacitor 2, while the terminal b is connected to the terminal b of the eleventh switch SW11.

The microcomputer I/F 11 inputs a control signal Ctl from a not-shown microcomputer through the third pad PD3. The register 12 temporarily stores and outputs the control signal Ctl input from the microcomputer I/F 11. The control signal Ctl is a signal for switching the eleventh and twelfth switches SW11 and SW12 to either the terminal a sides or the terminal b sides.

Here, in order to obtain a reference frequency necessary at a circuit such as an FM broadcasting receiving function, an MP3 playback function or an FM transmitter, when an exclusive crystal oscillator for the circuit is connected to the first pad PD1, the control signal Ctl switching the eleventh and twelfth switches SW11 and SW12 to the terminal a sides is sent from a not-shown microcomputer to the IC chip 50. Then, the control signal Ctl is input from the microcomputer I/F 11 to be held in the register 12.

On the other hand, when the IC chip 50 is used as an external input buffer circuit inputting a reference frequency signal produced by using an external crystal oscillator such as an RTC oscillation apparatus, the control signal Ctl switching the eleventh and twelfth switches SW11 and SW12 to the terminal b sides is sent from the not-shown microcomputer to the IC chip 50. Then, the control signal is input from the microcomputer I/F 11 to be held in the register 12.

It is possible to form the clapp oscillation circuit and the buffer circuit 55 by switching the eleventh and twelfth switches SW11 and SW12 to the terminal a sides. On the other hand, when the eleventh and twelfth switches SW11 and SW12 are switched to the terminal b sides, the first capacitor 1 functions as a coupling capacitor for cutting a DC component and the buffer circuit 55 is connected to a subsequent stage thereof through the transistor 52.

It is also possible that a switch is provided between the coil 51 and a grounding wire and turning off the switch cuts the coil 51 from the circuit when switching the eleventh and twelfth switches SW11 and SW12 to the terminal b sides.

Additionally, the buffer circuit 55 is not necessarily integrated into the IC chip 50 in the fifth embodiment.

In the first to fifth embodiments, each switch SW1 to SW12 may be an Nch or Pch MOS transistor, or a CMOS transistor.

Also, in the first to fifth embodiments, an example is shown in which the microcomputer I/F 11, the register 12 and the inverters 13 and 14 are integrated into the IC chip, while these may be formed outside the IC chip.

Additionally, in the first to fifth embodiments, an example of using the crystal oscillator as an oscillator is described, while the present invention is not limited thereto. Another oscillator, for example, a ceramic oscillator, a lithium tantalate oscillator or a rubidium cesium oscillator may be used.

While the first to fifth embodiments only show a concrete example for carrying out the present invention, the technical scope of the present invention should not be limited thereto. Thus, various modifications and changes may be made thereto without departing from the spirit and the main features of the present invention.

### INDUSTRIAL APPLICABILITY

The present invention is useful for an oscillation circuit integrated into a semiconductor chip.

1. An oscillation circuit integrated into a semiconductor chip, comprising:
a first pad having one end of an external oscillator of the semiconductor chip connected thereto;
a second pad having the other end of the oscillator connected thereto;
an CR oscillation circuit connected to the first pad and the second pad; and
a first switch switching presence or absence of a connection of a first capacitor of the CR oscillation circuit to a grounding wire.

2. The oscillation circuit according to claim 1, further comprising:
a second switch switching presence or absence of a connection of a second capacitor of the CR oscillation circuit to a grounding wire.

3. The oscillation circuit according to claim 1 or 2, further comprising:
a switch switching either connecting the first capacitor to the grounding wire through the first switch or connecting the first capacitor to an amplifier circuit of the CR oscillation circuit.

4. The oscillation circuit according to claim 2, further comprising:
a switch switching either connecting the first capacitor to the grounding wire through the second switch or connecting the second capacitor to an amplifier circuit of the CR oscillation circuit.

5. An oscillation circuit integrated into a semiconductor chip, comprising:
a first pad having one end of an external oscillator of the semiconductor chip connected thereto;
a second pad having the other end of the oscillator connected thereto;
a first capacitor and a first switch connected in series between the first pad and a grounding wire;
a second capacitor connected between the second pad and the grounding wire; and
an inverting amplifier and a feedback resistance connected in parallel between the first pad and the second pad.

6. The oscillation circuit according to claim 5, further comprising:
a second switch connected in series to the second capacitor between the second pad and the grounding wire.

7. The oscillation circuit according to claim 5, further comprising:
a third switch connected between the first pad and a common input terminal of the inverting amplifier and the feedback resistance;
a fourth switch connected between the second pad and a common output terminal of the inverting amplifier and the feedback resistance; and
a fifth switch connected in parallel to the third switch between one end of the first capacitor and the first pad, and
wherein the first switch is connected between the one end of the first capacitor and the grounding wire, and
on/off of the first, third and fourth switches is performed by a first control signal and on/off of the fifth switch is performed by a second control signal having an opposite phase to the first control signal.

8. The oscillation circuit according to claim 7, further comprising:
a second switch connected in series to the second capacitor between the second pad and the grounding wire;
wherein on/off of the second switch is performed by the first control signal.

9. The oscillation circuit according to claim 8, further comprising:
a sixth switch connected between one end of the first capacitor and one end of the second capacitor;
a seventh switch connected between the other end of the first capacitor and the other end of the second capacitor; and
an eighth switch connected between an output terminal of the inverting amplifier and the other end of the second capacitor;
wherein on/off of the sixth and seventh switches is performed by the second control signal and on/off of the eighth switch is performed by the first control signal.

10. An oscillation circuit integrated into a semiconductor chip, comprising:
a first pad having one end of an external oscillator of the semiconductor chip connected thereto;
a second pad having the other end of the oscillator connected thereto;
a first capacitor connected between the first pad and a grounding wire;
an inverting amplifier and a feedback resistance connected in parallel between the first pad and the second pad;
a ninth switch connected to an output terminal of the inverting amplifier and the feedback resistance;
a second capacitor connected between the ninth switch and the grounding wire;
a tenth switch connected between the second capacitor, the second pad and the grounding wire; and
a buffer circuit connected to an output terminal of the ninth switch.

11. An oscillation circuit integrated into a semiconductor chip, comprising:
a first pad having an external oscillator of the semiconductor chip connected;
a Colpitts or clapp oscillation circuit connected to the first pad;
an eleventh switch connected between a first capacitor of the Colpitts or clapp oscillation circuit and the first pad; and
a twelfth switch connected between the first capacitor of the Colpitts or clapp oscillation circuit, a second capacitor and the eleventh switch.
